(19) United States
(12) Patent Application Publication
(10) Pub. No.: US 2026/0362830 A1
(43) Pub. Date: Nov. 12, 2026

(54) SOLID-STATE IMAGING ELEMENT

(71) Applicant: SONY SEMICONDUCTOR SOLUTIONS CORPORATION, Kanagawa (JP)

(72) Inventor: Masashi BANDO, Kanagawa (JP)

(73) Assignee: SONY SEMICONDUCTOR SOLUTIONS CORPORATION, Kanagawa (JP)

(21) Appl. No.: 19/121,606

(22) PCT Filed: Oct. 24, 2023
(86) PCT No.: PCT/JP2023/038366

§ 371 Date: Apr. 16, 2025

(30) Foreign Application Priority Data
Nov. 2, 2022 (JP) 2022-176089

(51) Int. Cl. H10F 39/00

(52) U.S. Cl. CPC H10F 39/8023; H10F 39/8037

(57) ABSTRACT

A solid-state imaging element and method of manufacturing the same is provided to effectively achieve both suppression of sensitivity variations between the pixels due to the anisotropy of the color mixture and an improvement in layout efficiency. The solid-state imaging element includes a plurality of transistors; and a plurality of pixels arranged two-dimensionally. In the imaging element adjacent pixels may share at least one transistor. In the imaging device each pixel includes a first and a second silicon region and a first and a second silicon oxide film region, each silicon oxide film region surrounds a respective silicon region in a plan view.

### CROSS REFERENCE TO RELATED APPLICATIONS

This application claims the benefit of Japanese Priority Patent Application JP 2022-176089 filed Nov. 2, 2022, the entire contents of which are incorporated herein by reference.

### TECHNICAL FIELD

The present disclosure relates to a solid-state imaging element.

### BACKGROUND ART

In recent years, in a solid-state imaging element typified by a CMOS (Complementary Metal-Oxide-Semiconductor) image sensor, miniaturization of each pixel has been desired as the number of pixels has been increased. Under such circumstances, a high degree of freedom of layout in a back illumination type CMOS image sensor is utilized to share transistors between pixels and use power supply nodes and electrodes in a shared manner. Effective use of a layout space is thereby achieved.

PTL 1 discloses a solid-state imaging element in which an FD (floating diffusion) is shared by eight pixels. PTL 1 discloses that variations in sensitivity (output) characteristic between pixels of the same color within a pixel-shared unit can be suppressed by providing symmetry to an arrangement layout of light receiving portions and transistors in the pixel-shared unit. In addition, PTL 1 discloses that a wiring capacitance can be increased by laying out wiring extending in a horizontal direction with symmetry in addition to linear wiring in a vertical direction in the pixel-shared unit.

### CITATION LIST

### Patent Literature

PTL 1: PCT Patent Publication No. WO2016/163240

### SUMMARY

### Technical Problem

In recent years, for security applications and sensing applications, there has been an increasing need to perform imaging that uses near infrared rays (NIR: Near Infrared Rays). Light in an NIR wavelength range with a relatively large depth of penetration into silicon (Si) may reach a deep portion of a silicon member of the solid-state imaging element. In such a case, the light in the NIR wavelength range may be reflected at a substance boundary (Si/Si oxide film interface or the like) in the deep portion of the silicon member and enter an adjacent pixel. As a result, an optical color mixture is caused.

Particularly in a case where the pixel layout of silicon regions and silicon oxide film regions does not have translational symmetry, the color mixture caused by the reflection in the deep portion of the silicon member has anisotropy between pixels according to the azimuth angle of the incident light. Therefore, variations (signal imbalance) occur in sensitivity between pixels. As a result, the image quality of a photographed image (output image) is degraded. The anisotropy of such a color mixture tends to depend greatly on the periodicity of a pixel separation pattern of silicon and silicon oxide film.

In contrast, in a case where the pixel layout has translational symmetry, even when the color mixture due to the reflection in the deep portion of the silicon member occurs, such a color mixture basically occurs to a similar degree in all of pixels. Thus, sensitivity (output) does not vary easily between the pixels. However, even in the case where the pixel layout has translational symmetry, when the layout pattern of the silicon regions and the silicon oxide film regions in each pixel is complex, an area occupied by electrodes and wiring is increased. As a result, it is difficult to achieve excellent layout efficiency in each pixel.

According to an embodiment of the present disclosure, it is desirable to provide a technology that is advantageous in achieving excellent layout efficiency in each pixel while suppressing sensitivity variations between pixels.

### BRIEF DESCRIPTION OF DRAWINGS

FIG. 1 illustrates an example of a schematic sectional configuration of an imaging element and is a diagram of assistance in explaining occurrence of a color mixture caused by reflection of incident light incident on the imaging element.

FIG. 2 is a partial plan view of an imaging element and illustrates, in a see-through manner, an example of a pixel layout having translational symmetry between pixels adjacent to each other in pixel array directions (an x-direction and a y-direction).

FIG. 3 is a partial plan view of an imaging element and illustrates, in a see-through manner, an example of a pixel layout having mirror symmetry between pixels adjacent to each other in the x-direction and having translational symmetry between pixels adjacent to each other in the y-direction.

FIG. 4 is a partial plan view of an imaging element and illustrates, in a see-through manner, an example of a pixel layout that is advantageous in suppressing sensitivity variations and achieving excellent layout efficiency.

FIG. 5 is a partial plan view of an imaging element and illustrates, in a see-through manner, another example of the pixel layout (layout of silicon regions and silicon oxide film regions in particular) that is advantageous in suppressing sensitivity variations and achieving excellent layout efficiency.

FIG. 6 is a partial plan view of an imaging element and illustrates, in a see-through manner, another example of the pixel layout (layout of the silicon regions and the silicon oxide film regions in particular) that is advantageous in suppressing sensitivity variations and achieving excellent layout efficiency.

FIG. 7 illustrates an example of a schematic sectional configuration of an imaging element including an FTI pixel separating portion and is a diagram of assistance in explaining occurrence of a color mixture caused by the reflection of incident light incident on the imaging element.

FIG. 8 is a plan view of an imaging element including an FTI pixel separating portion and illustrates, in a see-through manner, an example of a pixel layout that is advantageous in suppressing sensitivity variations and achieving excellent layout efficiency.

FIG. 9 is a plan view of an imaging element including an FTI pixel separating portion and illustrates, in a see-through manner, an example of a pixel layout that is advantageous in suppressing sensitivity variations and achieving excellent layout efficiency.

FIG. 10 is a plan view of an imaging element including an FTI pixel separating portion and illustrates, in a see-through manner, an example of a pixel layout that is advantageous in suppressing sensitivity variations and achieving excellent layout efficiency.

FIG. 11 illustrates an example of a schematic sectional configuration of an imaging element having a two-stage pixel structure.

FIG. 12 illustrates an example of a circuit configuration including a first substrate and a second substrate illustrated in FIG. 11 and particularly illustrates an example of a layout of a Voltage-Domain type global shutter CMOS image sensor.

FIG. 13 illustrates an example of a schematic sectional configuration of an imaging element having a two-stage pixel structure.

FIG. 14 is a partial plan view illustrating an example of the pixel layout of the first substrate (first floor) of an imaging element having a two-stage pixel structure.

FIG. 15 is a partial plan view illustrating an example of the pixel layout of the first substrate (first floor) of an imaging element having a two-stage pixel structure.

FIG. 16 is a partial plan view illustrating an example of the pixel layout of the first substrate (first floor) of an imaging element having a two-stage pixel structure.

FIG. 17 illustrates a general configuration of an example of an imaging element having a multiple-stage pixel structure.

FIG. 18 is a circuit diagram illustrating an example of sensor pixels and a readout circuit.

FIG. 19 illustrates an example of a sectional configuration in a vertical direction of the imaging element.

FIG. 20 illustrates, on an enlarged scale, a part where a first substrate and a second substrate are connected to each other (see a reference sign “XX” in FIG. 19) in the imaging element.

FIG. 21 illustrates, on an enlarged scale, a part where the second substrate and a third substrate are connected to each other (see a reference sign “XXI” in FIG. 19) in the imaging element.

FIG. 22 is a diagram of assistance in explaining a configuration of imaging devices and electronic apparatuses that use a solid-state imaging element to which the present technology is applied.

FIG. 23 is a view depicting an example of a schematic configuration of an endoscopic surgery system.

FIG. 24 is a block diagram depicting an example of a functional configuration of a camera head and a camera control unit (CCU).

FIG. 25 is a block diagram depicting an example of schematic configuration of a vehicle control system.

FIG. 26 is a diagram of assistance in explaining an example of installation positions of an outside-vehicle information detecting section and an imaging section.

### DESCRIPTION OF EMBODIMENTS

Typical embodiments of the present disclosure will be described with reference to the drawings.

In the following, unless otherwise specified, description will be made on the basis of the directions of devices illustrated in corresponding drawings. However, the directions of actual devices are understood appropriately regardless of the directions in the following description.

A solid-state imaging element according to an embodiment of the present disclosure is also referred to as an image sensor. In the following description, the solid-state imaging element according to an embodiment of the present disclosure is also referred to simply as an “imaging element.” In addition, a semiconductor substrate including a semiconductor such as silicon is also referred to simply as a “substrate” in the following description.

### First Embodiment

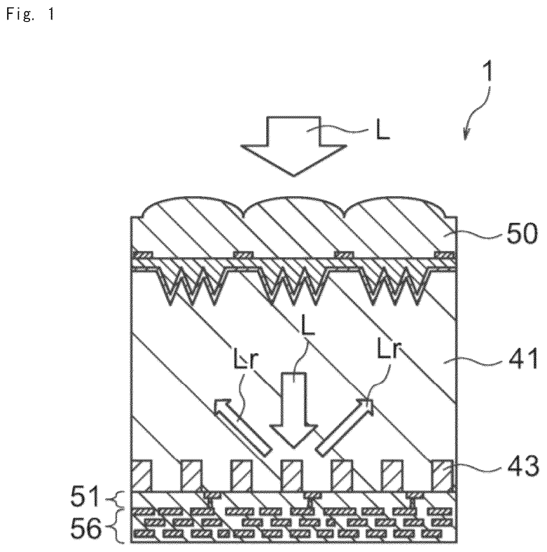

FIG. 1 illustrates an example of a schematic sectional configuration of an imaging element 1. FIG. 1 is a diagram of assistance in explaining occurrence of a color mixture caused by reflection of incident light L incident on the imaging element 1.

The incident light L (photographing light) is made incident on a photodiode 41 via a light receiving lens 50 and is received in the photodiode 41. The photodiode 41 provided in each pixel outputs a current corresponding to an amount of light received therein. The current from the photodiode 41 flows into a wiring layer 56 via wiring (a via or the like) provided in an interlayer insulating film 51.

Pixel separating portions 43 (for example, an STI: Shallow Trench Isolation) are provided between the photodiodes 41 of pixels 12 adjacent to each other to prevent occurrence of leakage current between the pixels 12 adjacent to each other.

Light of the incident light L reaching a bottom portion of the photodiode 41 may be reflected at an interface of the photodiode 41 (typically, a boundary surface between the photodiode 41 and the interlayer insulating film 51). An optical color mixture occurs when reflected light Lr thus generated enters adjacent pixels from the original incidence pixel.

A wavelength of the incident light L is not limited to any specific kind, but light in a long wavelength range (for example, near infrared rays or light having a longer wavelength) may be used as the incident light L. In particular, light having longer wavelengths tend to have higher transmissibility. The technology of the present disclosure can therefore exert effects thereof more advantageously in a case where the incident light L is light in a long wavelength range.

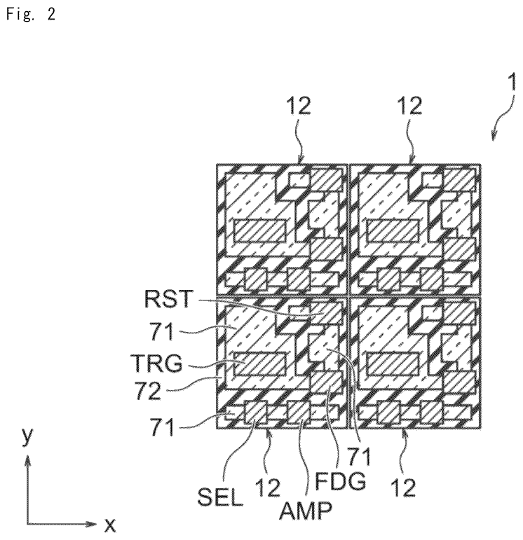

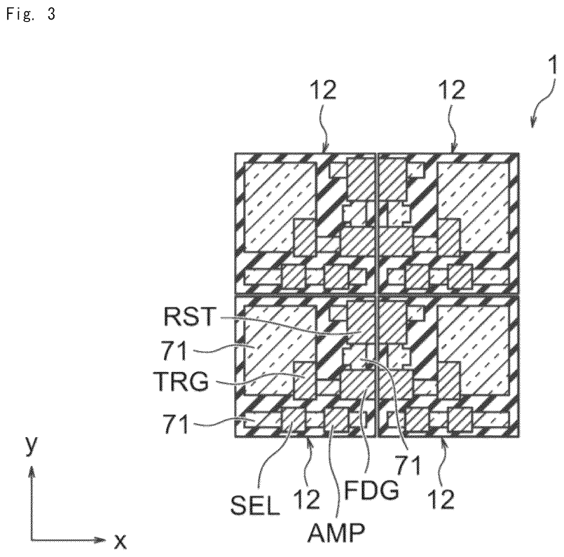

FIG. 2 is a partial plan view of an imaging element 1 and illustrates, in a see-through manner, an example of a pixel layout having translational symmetry between pixels 12 adjacent to each other in pixel array directions (an x-direction and a y-direction). FIG. 3 is a partial plan view of an imaging element 1 and illustrates, in a see-through manner, an example of a pixel layout having mirror symmetry between pixels 12 adjacent to each other in the x-direction and having translational symmetry between pixels 12 adjacent to each other in the y-direction. FIG. 2 and FIG. 3 do not illustrate other devices provided in each pixel 12.

The imaging element 1 has a large number of pixels 12 arranged in the pixel array directions (the x-direction and the y-direction). FIG. 2 and FIG. 3 illustrate only four pixels arranged in the x-direction and the y-direction that form a right angle to each other.

Silicon regions 71, silicon oxide film regions 72, and various types of transistors in FIG. 2 have a layout (arrangement) of translational symmetry between the pixels 12 adjacent to each other. In a case where each of the pixels 12 which have translational symmetry and are illustrated in FIG. 2 is translated in a pixel array direction and is superposed on an adjacent pixel 12, the layout of the pixel 12 matches that of the adjacent pixel 12. FIG. 2 illustrates, as an example of the various types of transistors, a reset transistor RST, a transfer transistor TRG, a selecting transistor SEL, an amplifier transistor AMP, and an FD transfer transistor FDG.

On the other hand, silicon regions 71, silicon oxide film regions 72, and various types of transistors illustrated in FIG. 3 have mirror symmetry between pixels 12 adjacent to each other in the x-direction. The layout of each of the pixels 12 illustrated in FIG. 3 is axisymmetric to the layout of a pixel 12 adjacent thereto in the x-direction, but does not have translational symmetry to the layout of the pixel 12 adjacent thereto in the x-direction.

In the imaging element 1 illustrated in FIG. 2, no transistor is shared between pixels 12 adjacent to each other, and each pixel 12 has various types of transistors unique thereto. According to the FEOL (Front-End-Of-Line) layout as illustrated in FIG. 2 which layout has translational symmetry between pixels 12 adjacent to each other, it is possible to suppress sensitivity variations caused by the anisotropy of the color mixture, but it is difficult to achieve excellent layout efficiency in each of the pixels 12.

On the other hand, in the imaging element 1 illustrated in FIG. 3, FD transfer transistors FDG and reset transistors RST are shared between pixels 12 adjacent to each other in the x-direction. According to the layout having mirror symmetry between pixels 12 adjacent to each other as illustrated in FIG. 3, it is possible to achieve excellent layout efficiency by sharing some of electrodes between pixels 12 adjacent to each other, but anisotropy occurs in the color mixture and thus causes sensitivity variations between the pixels 12.

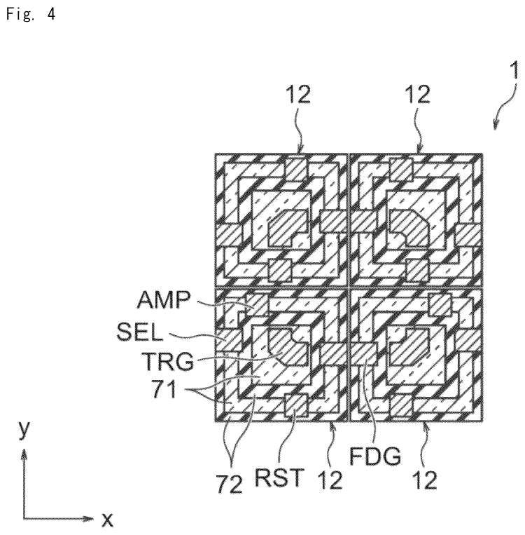

FIG. 4 is a partial plan view of an imaging element 1 and illustrates, in a see-through manner, an example of a pixel layout that is advantageous in suppressing sensitivity variations and achieving excellent layout efficiency. FIG. 4 does not illustrate other devices provided in each pixel 12.

Each pixel 12 of the imaging element 1 illustrated in FIG. 4 includes two silicon regions 71 and two silicon oxide film regions 72 surrounding the respective silicon regions 71. In embodiments, the second silicon oxide film region 72 surrounds an outer perimeter of each pixel.

The two silicon regions 71 include one rectangular (square) central silicon region 71 disposed in the center of each pixel 12 and one peripheral silicon region 71 inside which the central silicon region 71 is disposed.

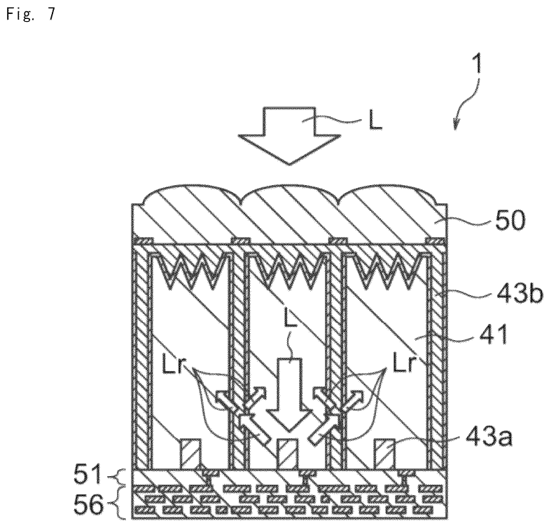

The central silicon region 71 includes a photodiode 41 (see FIG. 7). The peripheral silicon region 71 illustrated in FIG. 4 includes two parts extending in parallel with the x-direction and two parts extending in parallel with the y-direction and has a planar shape of a rectangular frame.

Thus, in the example illustrated in FIG. 4, the arrangement of the silicon regions 71 and the silicon oxide film regions 72 in each pixel 12 has mirror symmetry with respect to the pixel array directions (the x-direction and the y-direction) and has four-time symmetric rotational symmetry. The silicon regions 71 and the silicon oxide film regions 72 of each pixel 12 having four-time symmetric rotational symmetry before and after being rotated by 90 degrees about an axis passing through the center of each pixel 12 (axis extending in a direction perpendicular to the x-direction and the y-direction) have matching layouts.

Further, in the example illustrated in FIG. 4, the arrangement of the silicon regions 71 and the silicon oxide film regions 72 has translational symmetry between pixels 12 adjacent to each other in each of the x-direction and the y-direction.

In the above-described pixel layout illustrated in FIG. 4, FD transfer transistors FDG and selecting transistors SEL (for example, gate electrodes) are shared between pixels 12 having mirror symmetry in the x-direction. In addition, reset transistors RST are shared between pixels 12 having mirror symmetry in the y-direction. On the other hand, translational symmetry between the pixels 12 adjacent to each other with regard to the arrangement of the silicon regions 71 and the silicon oxide film regions 72 is ensured.

Hence, according to the pixel layout illustrated in FIG. 4, it is possible to effectively achieve both suppression of sensitivity variations between the pixels 12 due to the anisotropy of the color mixture and an improvement in layout efficiency.

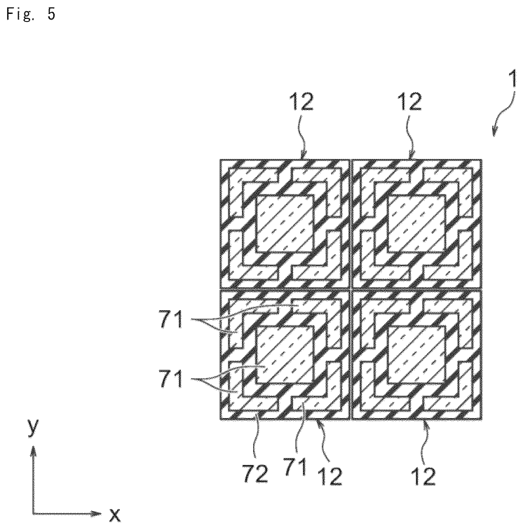

FIG. 5 is a partial plan view of an imaging element 1 and illustrates, in a see-through manner, another example of the pixel layout (layout of the silicon regions 71 and the silicon oxide film regions 72 in particular) that is advantageous in suppressing sensitivity variations and achieving excellent layout efficiency. FIG. 5 does not illustrate various types of transistors and other devices provided in each pixel 12.

Each pixel 12 of the imaging element 1 illustrated in FIG. 5 includes five silicon regions 71 and an integral silicon oxide film region 72 (one silicon oxide film region 72) surrounding each of the silicon regions 71.

The five silicon regions 71 include one rectangular (square) central silicon region 71 disposed in the center of each pixel 12 and four peripheral silicon regions 71 arranged around the central silicon region 71.

Each of the peripheral silicon regions 71 has an L-shaped planar shape including a part extending in the x-direction and a part extending in the y-direction and is disposed in the vicinity of a corner of the pixel 12 so as to cover the corresponding corner of the central silicon region 71 from the outside. In each of the x-direction and the y-direction of each pixel 12, two peripheral silicon regions 71 are arranged with a part of the silicon oxide film region 72 interposed therebetween.

Also in the example illustrated in FIG. 5, the arrangement of the silicon regions 71 and the silicon oxide film regions 72 in each pixel 12 has mirror symmetry with respect to the pixel array directions (the x-direction and the y-direction) and has four-time symmetric rotational symmetry. Further, the arrangement of the silicon regions 71 and the silicon oxide film regions 72 has translational symmetry between pixels 12 adjacent to each other in each of the x-direction and the y-direction.

Hence, the pixel layout illustrated in FIG. 5 also makes it possible to effectively achieve both suppression of sensitivity variations between the pixels 12 due to the anisotropy of the color mixture and an improvement in layout efficiency.

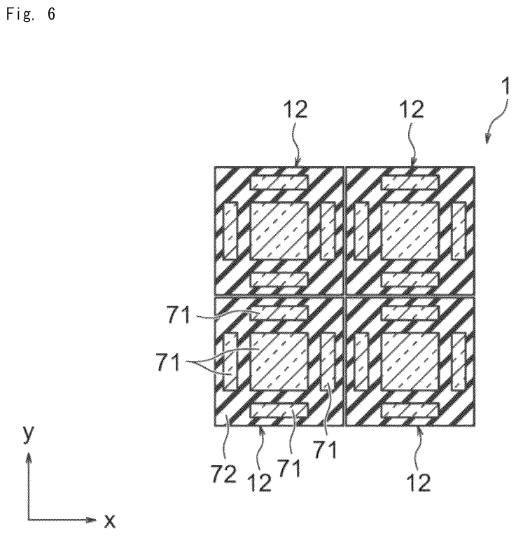

FIG. 6 is a partial plan view of an imaging element 1 and illustrates, in a see-through manner, another example of the pixel layout (layout of the silicon regions 71 and the silicon oxide film regions 72 in particular) that is advantageous in suppressing sensitivity variations and achieving excellent layout efficiency. FIG. 6 does not illustrate various types of transistors and other devices provided to each pixel 12.

Each pixel 12 of the imaging element 1 illustrated in FIG. 6 also includes five silicon regions 71 and an integral silicon oxide film region 72 (one silicon oxide film region 72) surrounding each of the silicon regions 71.

The five silicon regions 71 include one rectangular (square) central silicon region 71 disposed in the center of each pixel 12 and four peripheral silicon regions 71 arranged around the central silicon region 71.

Each of the four peripheral silicon regions 71 has a linear planar shape. The four peripheral silicon regions 71 include two peripheral silicon regions 71 extending in the x-direction and two silicon regions 71 extending in the y-direction. The four peripheral silicon regions 71 are arranged along four respective sides of the pixel 12 so as to cover the corresponding sides of the central silicon region 71 from the outside. In each of the x-direction and the y-direction of each pixel 12, two peripheral silicon regions 71 are located on opposite sides from each other with the central silicon region 71 interposed therebetween.

Also in the example illustrated in FIG. 6, the arrangement of the silicon regions 71 and the silicon oxide film regions 72 in each pixel 12 has mirror symmetry with respect to the pixel array directions (the x-direction and the y-direction) and has four-time symmetric rotational symmetry. Further, the arrangement of the silicon regions 71 and the silicon oxide film regions 72 has translational symmetry between pixels 12 adjacent to each other in each of the x-direction and the y-direction.

Hence, the pixel layout illustrated in FIG. 6 also makes it possible to effectively achieve both suppression of sensitivity variations between the pixels 12 due to the anisotropy of the color mixture and an improvement in layout efficiency.

Incidentally, while one central silicon region 71 is provided and one or four peripheral silicon regions 71 are provided in the examples illustrated in FIGS. 4 to 6 described above, the number, shape, and arrangement of these silicon regions 71 are not limited to any specific number or kind.

For example, the central silicon region 71 may have a planar shape other than a rectangular shape (square). The central silicon region 71 may, for example, have a planar shape of a regular polygon having an even number of vertices. In addition, one or four or a larger even number of peripheral silicon regions 71 may be provided.

Even in such a case, the arrangement of the silicon regions 71 and the silicon oxide film regions 72 in each pixel 12 can have mirror symmetry with respect to the pixel array directions (the x-direction and the y-direction) and have four-time symmetric rotational symmetry. Further, the arrangement of the silicon regions 71 and the silicon oxide film regions 72 can have translational symmetry between pixels 12 adjacent to each other in each of the x-direction and the y-direction. As a result, a pixel layout is realized which makes it possible to effectively achieve both suppression of sensitivity variations between the pixels 12 due to the anisotropy of the color mixture and an improvement in layout efficiency.

### Second Embodiment

The technology of the present disclosure can be applied also to an imaging element including pixel separating portions of what is generally called an FTI (Full Trench Isolation) structure.

FIG. 7 illustrates an example of a schematic sectional configuration of an imaging element 1 including an FTI pixel separating portion 43b. FIG. 7 is a diagram of assistance in explaining occurrence of a color mixture caused by reflection of the incident light L incident on the imaging element 1.

From a viewpoint of suppressing the color mixture, it is preferable that pixel separating portions that separate adjacent pixels 12 from each other include a pixel separating portion of what is generally called an FTI (Full Trench Isolation) type (FTI pixel separating portion 43b).

STI pixel separating portions 43a contribute to prevention of leakage current between pixels 12 adjacent to each other. However, the STI pixel separating portions 43a have a smaller height than those of photodiodes 41 in a laminating direction (height direction in FIG. 7).

On the other hand, the FTI pixel separating portion 43b extends in the laminating direction between pixels 12 adjacent to each other over a height equal to or larger than the photodiodes 41 and covers entire regions of the photodiodes 41 from sides (the x-direction and the y-direction). The FTI pixel separating portion 43b is thus arranged between the photodiodes 41 of the pixels adjacent to each other.

Incidentally, the FTI pixel separating portion 43b generally has a composition having an electrically insulating property such as silicon dioxide (SiO₂). The FTI pixel separating portion 43b including silicon dioxide can be regarded as a part of the silicon oxide film regions 72 (insulating regions).

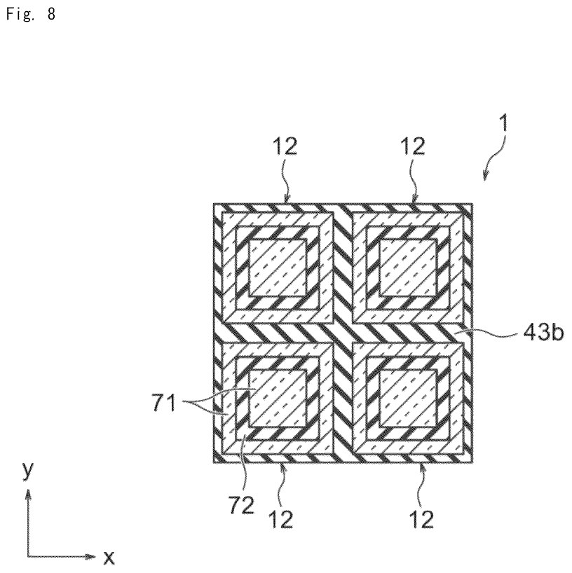

Each of FIGS. 8 to 10 is a plan view of an imaging element 1 including the FTI pixel separating portion 43b and illustrates, in a see-through manner, an example of a pixel layout that is advantageous in suppressing sensitivity variations and achieving excellent layout efficiency. FIGS. 8 to 10 do not illustrate various types of transistors and other devices provided in each pixel 12.

The pixel layouts illustrated in FIGS. 8 to 10 are pixel layouts obtained by applying the FTI pixel separating portion 43b to the pixel layouts (the silicon regions 71 and the silicon oxide film regions 72 in particular) illustrated in FIGS. 4 to 6, respectively.

That is, in the imaging elements 1 illustrated in FIGS. 8 to 10, respectively, each pixel 12 is demarcated by the FTI pixel separating portion 43b. The peripheral silicon regions 71 are in contact with the FTI pixel separating portion 43b, whereas the central silicon region 71 is not in contact with the FTI pixel separating portion 43b.

In the example illustrated in FIG. 8, for example, the single peripheral silicon region 71 of each pixel 12 is surrounded by the FTI pixel separating portion 43b, and the single central silicon region 71 is surrounded by the silicon oxide film region 72 different from the FTI pixel separating portion 43b.

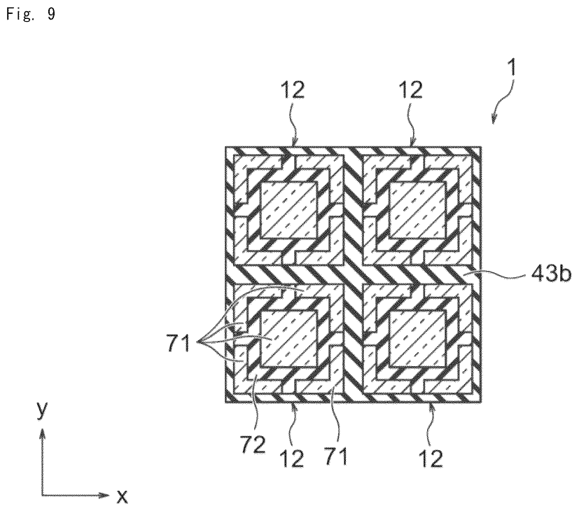

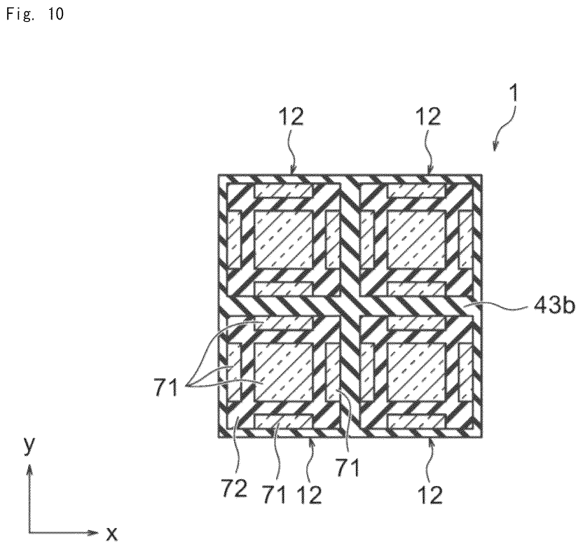

In addition, in the examples illustrated in FIG. 9 and FIG. 10, the four peripheral silicon regions 71 of each pixel 12 are surrounded by the FTI pixel separating portion 43b, or in the example illustrated in FIG. 8, for example, the single peripheral silicon region 71 of each pixel 12 is surrounded by the FTI pixel separating portion 43b, while the single central silicon region 71 is surrounded by the silicon oxide film region 72 different from the FTI pixel separating portion 43b.

Incidentally, also in the cases where the FTI pixel separating portion 43b is provided, the number, shape, and arrangement of silicon regions 71 (the central silicon region and the peripheral silicon regions) are not limited to any specific number or kind. For example, one or four or a larger even number of peripheral silicon regions 71 (semiconductor regions) in contact with the FTI pixel separating portion 43b may be provided.

### Third Embodiment

The technology of the present disclosure can be applied also to what is called a multilayer transistor pixel lamination type image sensor.

In recent years, a two-layer transistor pixel lamination type image sensor (hereinafter referred to as a “two-stage pixel structure imaging element”) has been proposed as an imaging element that is advantageous in miniaturizing pixels. The two-stage pixel structure imaging element is constructed by forming, in separate substrates, photodiodes and pixel transistors formed in the same substrate in related art, and laminating these substrates.

The technology of the present disclosure can produce actions and effects similar to those of the imaging element 1 according to the foregoing embodiment also in a case where the technology of the present disclosure is applied to such a two-stage pixel structure imaging element.

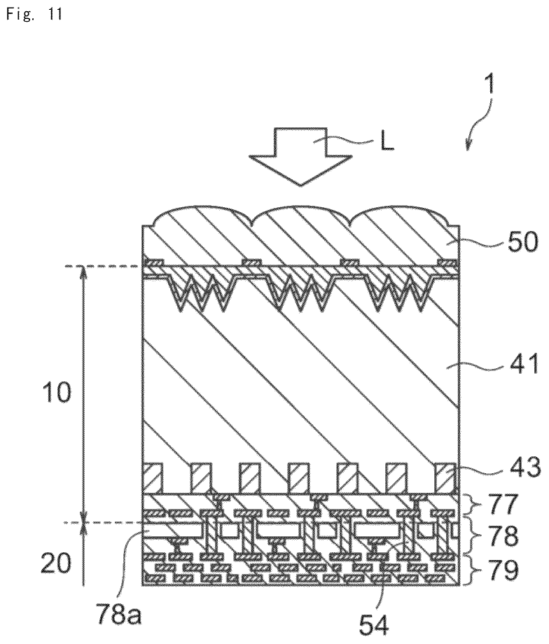

FIG. 11 illustrates an example of a schematic sectional configuration of an imaging element 1 having a two-stage pixel structure.

The imaging element 1 illustrated in FIG. 11 includes a first substrate 10 and a second substrate 20.

The first substrate 10 and the second substrate 20 are stacked on each other and are electrically connected to each other. A connection layer 78 is interposed at a boundary between the first substrate 10 and the second substrate 20 and is provided with a plurality of pieces of through wiring 54 that penetrates the connection layer 78 in the laminating direction (height direction in FIG. 11).

The first substrate 10 includes a photodiode 41, pixel separating portions 43 (for example, STI pixel separating portions), a wiring layer 77, and a part of the connection layer 78. The second substrate 20 includes a wiring layer 79 and a part of the connection layer 78. The wiring layer 77 and the wiring layer 79 arranged in such a manner as to be separated from each other by the connection layer 78 are electrically connected to each other via the through wiring 54. As a result, the first substrate 10 and the second substrate 20 are electrically connected to each other.

Each piece of wiring (including electrodes) provided in the wiring layer 77, the connection layer 78, and the wiring layer 79 is surrounded by an insulating film having an electrically insulating property. For example, the connection layer 78 includes a semiconductor layer 78a of silicon or the like, and each piece of through wiring 54 and the semiconductor layer 78a are electrically isolated from each other by the insulating film (for example, a silicon oxide film).

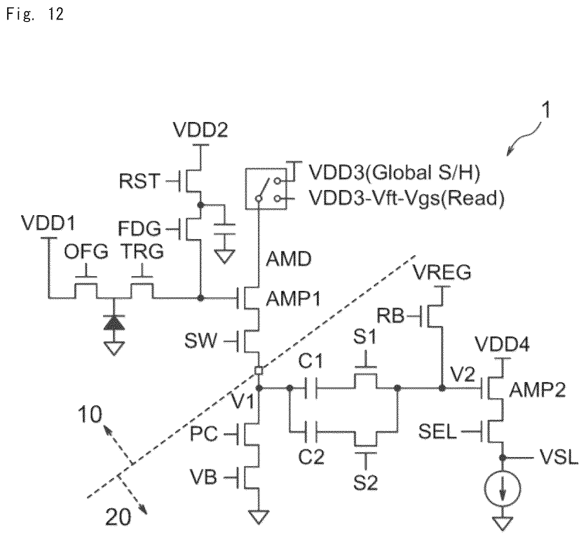

FIG. 12 illustrates an example of a circuit configuration including the first substrate 10 and the second substrate 20 illustrated in FIG. 11 and particularly illustrates an example of a layout of a Voltage-Domain global shutter CMOS image sensor (that is, a “VDGS CIS”).

A circuit illustrated in FIG. 12 includes a Sample/Hold (S/H) circuit for holding a signal. A circuit configuration on an upper left of a dotted line in FIG. 12 is formed in the first substrate 10. A circuit configuration on a lower right of the dotted line is formed in the second substrate 20.

The first substrate 10 is provided with a power supply VDD1, a power supply VDD2, a power supply VDD3, a discharging transistor OFG, a transfer transistor TRG, an FD transfer transistor FDG, a reset transistor RST, an amplifier transistor AMP1, and a switch SW. The power supply VDD1 and the transfer transistor TRG are connected to the discharging transistor OFG. The FD transfer transistor FDG and the amplifier transistor AMP1 are connected to the transfer transistor TRG. The power supply VDD2 and the FD transfer transistor FDG are connected to the reset transistor RST. The power supply VDD3 and the switch SW are connected to the amplifier transistor AMP1.

Incidentally, “AMD” denotes a processor, and “VDD3-Vft-Vgs (Read)” denotes “Voltage of Power Supply VDD3”−“Reset Feedthrough Voltage (Vft)”−“Gate-to-Source Voltage (Vgs).”

In the second substrate 20, a transistor supplied with a control signal PC from a vertical scanning circuit and a transistor to which a predetermined bias voltage VB is applied are connected to each other. The second substrate 20 is further provided with a capacitor C1, a capacitor C2, a transistor S1, a transistor S2, a transistor supplied with a control signal RB from the vertical scanning circuit, a voltage source VREG, a power supply VDD4, an amplifier transistor AMP2, and a selecting transistor SEL.

The switch SW of the first substrate 10 is connected via a node V1 to the transistor supplied with the control signal PC, the capacitor C1, and the capacitor C2.

The transistor S1 and the transistor S2 are respectively connected to the capacitor C1 and the capacitor C2 having a parallel connection mode. The transistor S1 and the transistor S2 are connected via a node V2 to the transistor supplied with the control signal RB and the amplifier transistor AMP2. The voltage source VREG is connected to the transistor supplied with the control signal RB. The power supply VDD4 and the selecting transistor SEL are connected to the amplifier transistor AMP2. A vertical signal line VSL is connected to the selecting transistor SEL.

In the VDGS circuit illustrated in FIG. 12, two-pixel x two-pixel sharing is realized by the node V2.

Incidentally, while the transfer transistor TRG is present in the first substrate 10 (first floor), another pixel transistor may be provided in the first substrate 10.

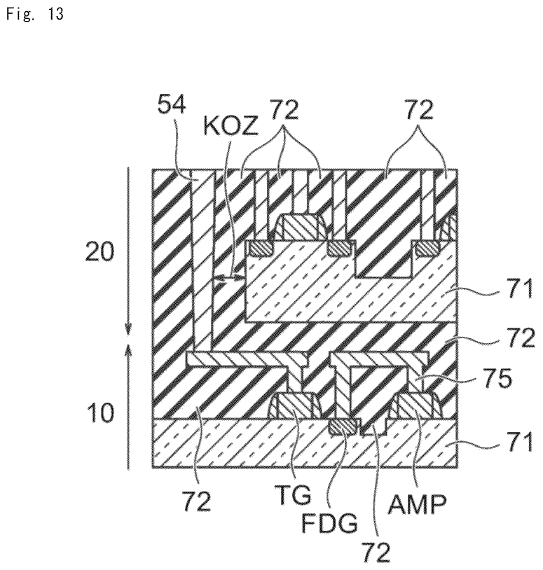

FIG. 13 illustrates an example of a schematic sectional configuration of an imaging element 1 having a two-stage pixel structure.

The imaging element 1 illustrated in FIG. 13 includes a first substrate 10 and a second substrate 20.

The first substrate 10 illustrated in FIG. 13 includes a silicon region 71, silicon oxide film regions 72, an amplifier transistor AMP, an FD transfer transistor FDG, and a transfer gate TG.

The second substrate 20 illustrated in FIG. 13 includes a silicon region 71, silicon oxide film regions 72, and various types of devices (including various types of transistors).

Transistors (for example, the FD transfer transistor FDG and the amplifier transistor AMP) are connected to each other via wiring 75 (for example, wiring including polysilicon). In addition, various types of devices of the first substrate 10 (for example, the transfer gate TG) and various types of devices of the second substrate 20 are each connected to through wiring 54 via the wiring 75 and are consequently electrically connected to each other via the through wiring 54.

Control lines and power supply wiring of the transistors formed in the first substrate 10 constituting a first floor and the second substrate 20 constituting a second floor are formed in the same BEOL (Back-End-Of-Line) process.

The gate electrodes of the transistors formed in the first substrate 10 and power supply nodes are connected to wiring and the like of the second substrate 20 via a plurality of pieces of the through wiring 54 (through vias). An interval KOZ (Keep-Out-Zone) where variations in processing accuracy are taken into consideration is secured between each piece of through wiring 54 and the silicon region 71 (semiconductor region) of the second substrate 20.

The more the number of transistors and power supply nodes formed in the first substrate 10 is increased, the more the number of pieces of through wiring 54 is increased. In particular, because the above-described interval KOZ needs to be secured for each piece of through wiring 54, an increase in the number of pieces of through wiring 54 sharply increases the scarcity of regions in the second substrate 20. As a result, layout efficiency in each pixel 12 is significantly decreased.

Further, when regions in the second substrate 20 become scarce, a necessity to reduce the size of various types of transistors arises. As a result, there is a fear of hindering an improvement in imaging characteristics of the imaging element 1.

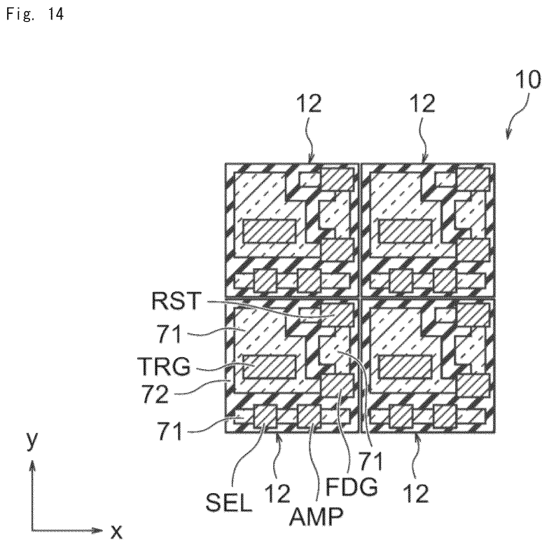

FIGS. 14 to 16 are partial plan views illustrating examples of the pixel layout of the first substrate 10 (first floor) of an imaging element 1 having a two-stage pixel structure. FIGS. 14 to 16 do not illustrate other devices.

The pixel layouts of the first substrates 10 illustrated in FIGS. 14 to 16 are similar to the pixel layouts of the imaging elements 1 illustrated in FIGS. 2 to 4.

Specifically, silicon regions 71, silicon oxide film regions 72, and various types of transistors of the first substrate 10 illustrated in FIG. 14 have a pixel layout having translational symmetry between pixels 12 adjacent to each other in the pixel array directions (the x-direction and the y-direction).

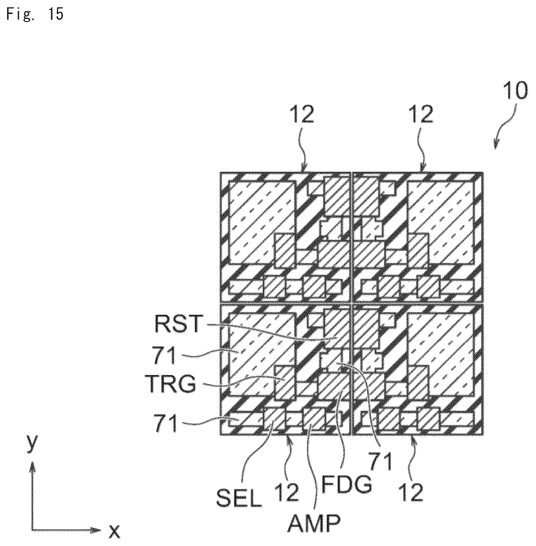

In addition, silicon regions 71, silicon oxide film regions 72, and various types of transistors of the first substrate 10 illustrated in FIG. 15 have mirror symmetry between pixels 12 adjacent to each other in the x-direction and have translational symmetry between pixels 12 adjacent to each other in the y-direction.

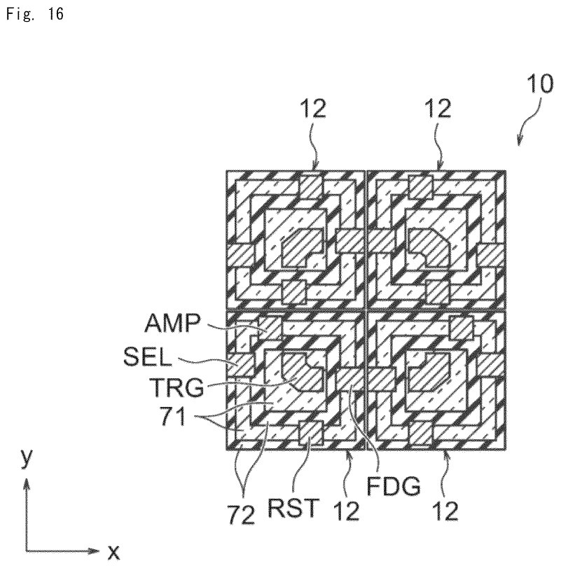

In addition, silicon regions 71 and silicon oxide film regions 72 of the first substrate 10 illustrated in FIG. 16 have mirror symmetry between pixels 12 with respect to the pixel array directions (the x-direction and the y-direction) and have four-time symmetric rotational symmetry in each pixel 12. Further, the arrangement of the silicon regions 71 and the silicon oxide film regions 72 has translational symmetry between pixels 12 adjacent to each other in each of the x-direction and the y-direction.

In the example illustrated in FIG. 14, the silicon regions 71, the silicon oxide film regions 72, and the various types of transistors do not have mirror symmetry between pixels 12 adjacent to each other. Therefore, through wiring 54 may not be shared between pixels 12 adjacent to each other. It is thus not possible to achieve an improvement in the layout efficiency of the second substrate 20 through a reduction in the number of pieces of through wiring 54.

The example illustrated in FIG. 15 is advantageous in prompting the sharing of the through wiring 54 between pixels 12 adjacent to each other, on the basis of the mirror symmetry of the silicon regions 71 and the silicon oxide film regions 72. However, as described above, sensitivity variations between pixels 12 due to the anisotropy of the color mixture tend to occur, thus hindering an improvement in the image quality of photographed images.

On the other hand, the example illustrated in FIG. 16 is advantageous in effectively achieving both suppression of sensitivity variations between the pixels 12 due to the anisotropy of the color mixture and realization of an improvement in layout efficiency.

The present inventor simulated the number of pieces of through wiring 54 necessary to implement circuit functions equivalent to each other in the imaging elements 1 (2×2 pixels 12 (a total of four pixels, in particular)) of the two-stage pixel structure adopting the first substrates 10 illustrated in FIGS. 14 to 16.

As a result, for circuit functions that necessitate 40 pieces of through wiring 54 in the imaging element 1 adopting the first substrate 10 of FIGS. 14, 30 pieces of through wiring 54 were necessary in the imaging element 1 adopting the first substrate 10 of FIG. 15. On the other hand, 28 pieces of through wiring 54 were necessary in the imaging element 1 adopting the first substrate 10 of FIG. 16. It is clear also from the simulation results that the pixel layout illustrated in FIG. 16 is advantageous in improving layout efficiency.

### Other Examples of Multiple-Stage Pixel Structure

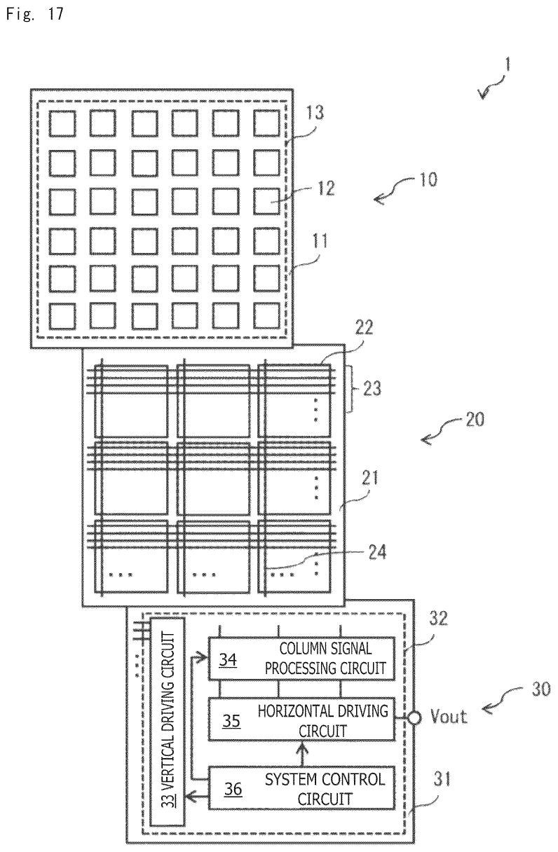

FIG. 17 illustrates a general configuration of an example of an imaging element 1 having a multiple-stage pixel structure.

The imaging element 1 illustrated in FIG. 17 includes three substrates (a first substrate 10, a second substrate 20, and a third substrate 30) and has a three-dimensional structure in which the three substrates are laminated to each other. The first substrate 10, the second substrate 20, and the third substrate 30 are laminated in this order.

The first substrate 10 has a semiconductor substrate 11. The semiconductor substrate 11 has a plurality of sensor pixels 12 that performs photoelectric conversion. The plurality of sensor pixels 12 is two-dimensionally arranged in the form of a matrix in a pixel region 13 in the first substrate 10.

The second substrate 20 has a semiconductor substrate 21. The semiconductor substrate 21 has a plurality of readout circuits 22 that outputs pixel signals based on charges output from the sensor pixels 12. One readout circuit 22 is assigned to four sensor pixels 12. The second substrate 20 has a plurality of pixel driving lines 23 extending in a row direction and a plurality of vertical signal lines 24 extending in a column direction.

The third substrate 30 has a semiconductor substrate 31. The semiconductor substrate 31 has a logic circuit 32 that processes the pixel signals. The logic circuit 32 includes, for example, a vertical driving circuit 33, a column signal processing circuit 34, a horizontal driving circuit 35, and a system control circuit 36. The logic circuit 32 (specifically, the horizontal driving circuit 35) outputs an output voltage Vout of each of the sensor pixels 12 to the outside. In the logic circuit 32, a low resistance region including silicide may be formed on a surface of an impurity diffusion region in contact with a source electrode and a drain electrode, for example. This silicide can include using a salicide (Self Aligned Silicide) process for CoSi₂, NiSi, or the like.

The vertical driving circuit 33, for example, selects the plurality of sensor pixels 12 in order in row units. The column signal processing circuit 34, for example, performs correlated double sampling (Correlated Double Sampling: CDS) processing on the pixel signal output from each of sensor pixels 12 in a row selected by the vertical driving circuit 33. By performing the CDS processing, the column signal processing circuit 34, for example, extracts the signal level of the pixel signal and retains pixel data corresponding to an amount of light received by each sensor pixel 12. The horizontal driving circuit 35, for example, outputs the pixel data retained in the column signal processing circuit 34 to the outside sequentially. The system control circuit 36, for example, controls the driving of each block (the vertical driving circuit 33, the column signal processing circuit 34, and the horizontal driving circuit 35) in the logic circuit 32.

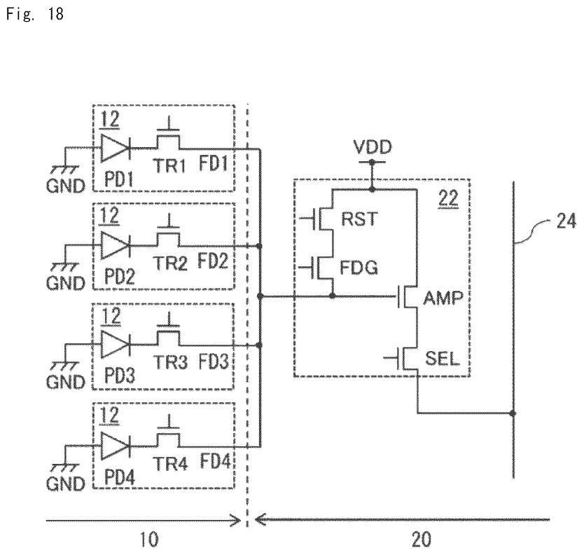

FIG. 18 is a circuit diagram illustrating an example of sensor pixels 12 and a readout circuit 22.

In the example illustrated in FIG. 18, four sensor pixels 12 share one readout circuit 22. The “sharing” in this case refers to the input of outputs of the four sensor pixels 12 to the common readout circuit 22.

The sensor pixels 12 have configurations in common to each other. In FIG. 18, in order to distinguish constituent elements of the respective sensor pixels 12 from each other, identification numbers (1, 2, 3, and 4) are attached to ends of reference signs of the constituent elements of the respective sensor pixels 12. In the following, in a case where the constituent elements of the respective sensor pixels 12 are to be distinguished from each other, the identification numbers are attached to the ends of the reference signs of the constituent elements of the respective sensor pixel 12, and in a case where the constituent elements of the respective sensor pixels 12 are not to be distinguished from each other, the identification numbers are not attached to the ends of the reference characters of the constituent elements of the respective sensor pixels 12.

Each sensor pixel 12 includes a photodiode PD, a transfer transistor TR electrically connected to the photodiode PD, and a floating diffusion FD electrically connected to the transfer transistor TR.

The photodiode PD is a photoelectric conversion element that generates a charge corresponding to an amount of received light by performing photoelectric conversion. A cathode of the photodiode PD is electrically connected to a source of the transfer transistor TR. An anode of the photodiode PD is electrically connected to a reference potential line (for example, a ground).

The transfer transistor TR is, for example, a CMOS transistor. A drain of the transfer transistor TR is electrically connected to the floating diffusion FD. A gate of the transfer transistor TR is electrically connected to a pixel driving line 23.

The floating diffusion FD temporarily retains the charge output from the photodiode PD and received by the floating diffusion FD via the transfer transistor TR. The floating diffusions FD of the plurality of sensor pixels 12 sharing one readout circuit 22 are electrically connected to each other and are electrically connected to an input terminal of the common readout circuit 22.

The readout circuit 22 includes a reset transistor RST, a selecting transistor SEL, an amplifier transistor AMP, and an FD transfer transistor FDG.

The FD transfer transistor FDG is provided between a source of the reset transistor RST and a gate of the amplifier transistor AMP. The FD transfer transistor FDG is used to change conversion efficiency, as will be described later.

The source of the reset transistor RST (input terminal of the readout circuit 22) is electrically connected to the floating diffusion FD via the FD transfer transistor FDG. A drain of the reset transistor RST is electrically connected to a power supply line VDD and a drain of the amplifier transistor AMP. A gate of the reset transistor RST is electrically connected to a pixel driving line 23 (see FIG. 17).

A source of the amplifier transistor AMP is electrically connected to a drain of the selecting transistor SEL via the FD transfer transistor FDG. The gate of the amplifier transistor AMP is electrically connected to the source of the reset transistor RST.

A source of the selecting transistor SEL (output terminal of the readout circuit 22) is electrically connected to a vertical signal line 24. A gate of the selecting transistor SEL is electrically connected to the pixel driving line 23 (see FIG. 17).

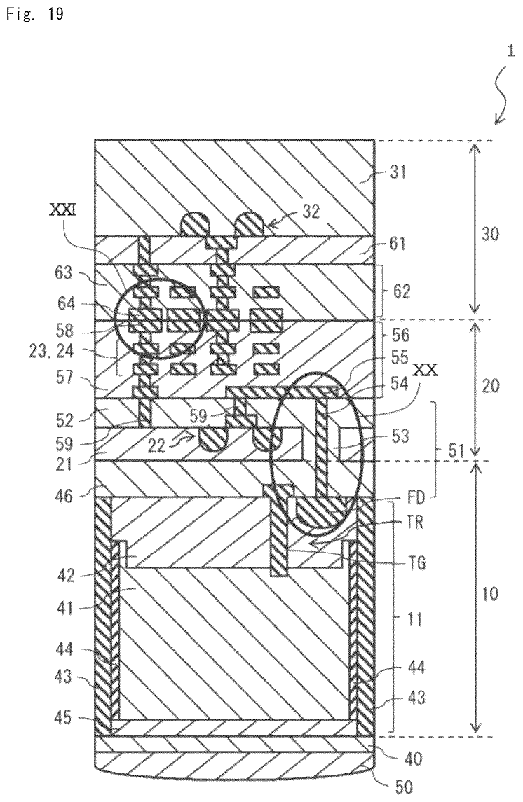

The transfer transistor TR in an on state transfers the charge of the photodiode PD to the floating diffusion FD. As illustrated in FIG. 19 to be described later, for example, the gate of the transfer transistor TR (transfer gate TG) penetrates a p-well layer 42 from a top surface of the semiconductor substrate 11 and extends to a depth reaching the photodiode 41 (corresponding to the photodiode PD). The reset transistor RST resets the potential of the floating diffusion FD to a predetermined potential. The reset transistor RST in an on state resets the potential of the floating diffusion FD to the potential of the power supply line VDD. The selecting transistor SEL controls a timing of output of a pixel signal from the readout circuit 22. The amplifier transistor AMP generates, as the pixel signal, a signal of a voltage corresponding to the level of the charge retained by the floating diffusion FD. The amplifier transistor AMP constitutes a source follower amplifier. The amplifier transistor AMP outputs the pixel signal of the voltage corresponding to the level of the charge generated in the photodiode PD. In a state in which the selecting transistor SEL is on, the amplifier transistor AMP amplifies the potential of the floating diffusion FD and outputs a voltage corresponding to the potential obtained after the amplification to the column signal processing circuit 34 via the vertical signal line 24. The reset transistor RST, the amplifier transistor AMP, and the selecting transistor SEL are, for example, CMOS transistors.

The on-off switching of the FD transfer transistor FDG changes conversion efficiency. In general, a pixel signal obtained by photographing in a dark place is relatively small. Thus, on the basis of Q=CV, when the charge-to-voltage conversion is performed, the larger the capacitance of the floating diffusion FD (FD capacitance C), the smaller the V obtained by the conversion into the voltage in the amplifier transistor AMP. On the other hand, a pixel signal obtained by photographing in a bright place is relatively large. Thus, when the FD capacitance C does not have a sufficient magnitude, the floating diffusion FD may not receive the charge of the photodiode PD. Further, the FD capacitance C may need to be sufficiently high such that the V obtained by the conversion in the amplifier transistor AMP does not become too high (in other words, such that the V obtained by the conversion in the amplifier transistor AMP becomes sufficiently low). On the basis of the above, in a case where the FD transfer transistor FDG is turned on, a gate capacitance is increased by an amount corresponding to the FD transfer transistor FDG, and the overall FD capacitance C is increased. On the other hand, in a case where the FD transfer transistor FDG is turned off, the overall FD capacitance C is decreased. It is thus possible to vary the FD capacitance C and thereby change conversion efficiency according to the on-off switching of the FD transfer transistor FDG.

Incidentally, the selecting transistor SEL may be provided between the power supply line VDD and the amplifier transistor AMP. In this case, the drain of the reset transistor RST is electrically connected to the power supply line VDD and the drain of the selecting transistor SEL. In addition, the source of the selecting transistor SEL is electrically connected to the drain of the amplifier transistor AMP, and the gate of the selecting transistor SEL is electrically connected to the pixel driving line 23 (see FIG. 17). In addition, the source of the amplifier transistor AMP (output terminal of the readout circuit 22) is electrically connected to the vertical signal line 24, and the gate of the amplifier transistor AMP is electrically connected to the source of the reset transistor RST.

The readout circuit 22 is not limited to the foregoing example. For example, the selecting transistor SEL and/or the FD transfer transistor FDG may not be provided to the readout circuit 22.

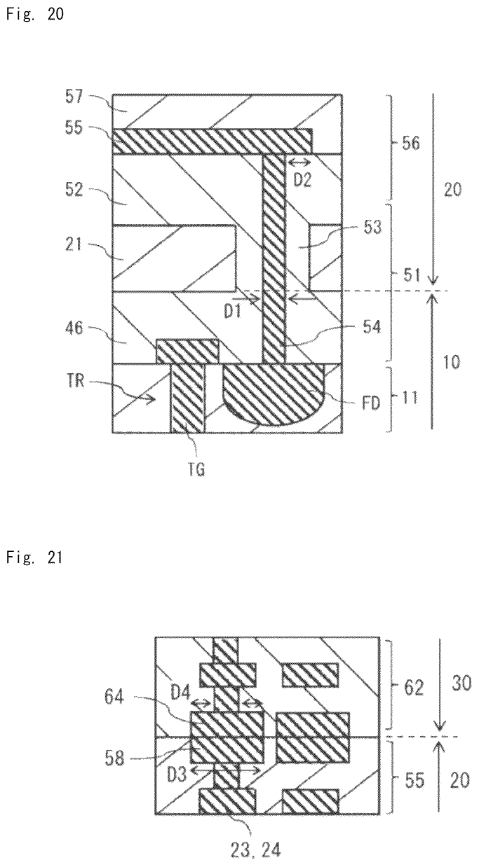

FIG. 19 illustrates an example of a sectional configuration in a vertical direction of the imaging element 1. FIG. 19 illustratively represents the sectional configuration of a part opposed to a sensor pixel 12 in the imaging element 1. FIG. 20 illustrates, on an enlarged scale, a part where the first substrate 10 and the second substrate 20 are connected to each other (see reference sign “IV” in FIG. 19) in the imaging element 1. FIG. 21 illustrates, on an enlarged scale, a part where the second substrate 20 and the third substrate 30 are connected to each other (see reference sign “V” in FIG. 19) in the imaging element 1.

The imaging element 1 illustrated in FIG. 19 includes a color filter 40 and a light receiving lens 50 provided on the undersurface side (light incidence surface side) of the first substrate 10 in addition to the first substrate 10, the second substrate 20, and the third substrate 30. For example, each color filter 40 and each light receiving lens 50 may be assigned to one sensor pixel 12 on a one-to-one basis. Thus, the imaging element 1 illustrated in FIG. 19 is the imaging element of a back illumination type.

An insulating layer 46 is laminated onto the semiconductor substrate 11 of the first substrate 10. The insulating layer 46 is a part of an interlayer insulating film 51 provided in a range including a boundary between the first substrate 10 and the second substrate 20. The insulating layer 46 is provided between the semiconductor substrate 11 of the first substrate 10 and the semiconductor substrate 21 of the second substrate 20. The semiconductor substrate 11 includes a silicon substrate. The semiconductor substrate 11, for example, includes a p-well layer 42 in a part of a top surface of the semiconductor substrate 11 and vicinities thereof and includes a photodiode 41 of a conductivity type different from that of the p-well layer 42 in the other region (a region deeper than the p-well layer 42). The p-well layer 42 includes a p-type semiconductor region. The photodiode 41 includes a semiconductor region of a conductivity type (specifically, an n-type) different from that of the p-well layer 42. The semiconductor substrate 11 includes a floating diffusion FD as a semiconductor region of a conductivity type (specifically the n-type) different from that of the p-well layer 42 such that the floating diffusion FD adjoins the p-well layer 42.

The first substrate 10 has the photodiode PD, the transfer transistor TR, and the floating diffusion FD for each sensor pixel 12. The first substrate 10 is provided with the transfer transistor TR and the floating diffusion FD in a part on the top surface side of the semiconductor substrate 11 (on an opposite side from the light incidence surface side (that is, on the second substrate 20 side)). The first substrate 10 has pixel separating portions 43 that separate each sensor pixel 12. The pixel separating portions 43 extend in a normal direction of the semiconductor substrate 11 (a direction perpendicular to the top surface of the semiconductor substrate 11). A pixel separating portion 43 is provided between two sensor pixels 12 adjacent to each other and electrically isolates the adjacent sensor pixels 12 from each other. The pixel separating portions 43 includes, for example, silicon oxide. The pixel separating portions 43 penetrate the semiconductor substrate 11.

The first substrate 10 further includes p-well layers 44 provided between the photodiode PD side and the pixel separating portions 43. The p-well layers 44 illustrated in FIG. 19 are in contact with side surfaces of the pixel separating portions 43 and are in contact with side surfaces of the photodiode PD. The p-well layer 44 includes a semiconductor region of a conductivity type (specifically, a p-type) different from that of the photodiode PD.

The first substrate 10 further includes a fixed charge film 45 located on an undersurface side with respect to the photodiode PD. The fixed charge film 45 illustrated in FIG. 19 is in contact with the photodiode PD. The fixed charge film 45 is negatively charged to suppress occurrence of a dark current caused by an interface level on a light receiving surface side of the semiconductor substrate 11. The fixed charge film 45 includes, for example, insulating film having a negative fixed charge. The fixed charge film 45 includes, for example, hafnium oxide, zircon oxide, aluminum oxide, titanium oxide, or tantalum oxide. An electric field induced by the fixed charge film 45 forms a hole accumulation layer at an interface on the light receiving surface side of the semiconductor substrate 11. As a result, occurrence of electrons from the interface is suppressed.

The color filter 40 is provided on the undersurface side of the semiconductor substrate 11. The color filter 40 illustrated in FIG. 19 is in contact with the fixed charge film 45 and is positioned so as to be opposed to the sensor pixel 12 (photodiode 41, in particular) with the fixed charge film 45 interposed therebetween. The light receiving lens 50 is provided in a position opposed to the sensor pixel 12 (photodiode 41, in particular) with the color filter 40 and the fixed charge film 45 interposed therebetween. The light receiving lens 50 illustrated in FIG. 19 is in contact with the color filter 40.

An insulating layer 52 is laminated onto the semiconductor substrate 21 of the second substrate 20. The insulating layer 52 is a part of the interlayer insulating film 51. The insulating layer 52 is provided between the semiconductor substrate 21 of the second substrate 20 and the semiconductor substrate 31 of the third substrate 30. The semiconductor substrate 21 includes a silicon substrate. The second substrate 20 has one readout circuit 22 for each set of four sensor pixels 12. The second substrate 20 illustrated in FIG. 19 is provided with the readout circuit 22 on the top surface side (third substrate 30 side) of the semiconductor substrate 21. The second substrate 20 is laminated to the first substrate 10 in a state in which the undersurface of the semiconductor substrate 21 is directed toward the top surface of the semiconductor substrate 11. That is, the second substrate 20 is laminated to the first substrate 10 in what is generally called a face-to-back mode. The second substrate 20 further includes an insulating layer 53 in the same layer as the semiconductor substrate 21, the insulating layer 53 penetrating the semiconductor substrate 21. The insulating layer 53 is a part of the interlayer insulating film 51. The insulating layer 53 is provided so as to cover the side surface of the through wiring 54 to be described later.

A laminate including the first substrate 10 and the second substrate 20 has the interlayer insulating film 51 and the through wiring 54 that penetrates the interlayer insulating film 51. The laminate may, for example, have one piece of through wiring 54 for each sensor pixel 12. The through wiring 54 extends in a normal direction of the semiconductor substrate 21 and penetrates a part of the interlayer insulating film 51 which part includes the insulating layer 53. The first substrate 10 and the second substrate 20 are electrically connected to each other by the through wiring 54. Specifically, the through wiring 54 is electrically connected to the floating diffusion FD and the connection wiring 55 to be described later.

The laminate including the first substrate 10 and the second substrate 20 has additional through wiring (not illustrated) in the interlayer insulating film 51. The additional through wiring also extends in the normal direction of the semiconductor substrate 21, penetrates the part including the insulating layer 53, and electrically connects the first substrate 10 and the second substrate 20 to each other. Specifically, certain through wiring may be electrically connected to the p-well layer 42 in the semiconductor substrate 11 and wiring in the second substrate 20. In addition, another piece of through wiring may be electrically connected to each of the transfer gate TG and a pixel driving line 23.

The insulating layer 52 is provided with a plurality of connecting portions 59 electrically connected to the readout circuit 22 and the semiconductor substrate 21. The second substrate 20 further includes a wiring layer 56 provided on the insulating layer 52. The wiring layer 56 includes an insulating layer 57 and a plurality of pixel driving lines 23 and a plurality of vertical signal lines 24 provided in the insulating layer 57. The wiring layer 56 further includes a plurality of pieces of connection wiring 55 provided in the insulating layer 57. One piece of connection wiring 55 is provided for each set of four sensor pixels 12. The connection wiring 55 electrically connects, to each other, pieces of through wiring 54 electrically connected to the floating diffusions FD included in the four sensor pixels 12 sharing the readout circuit 22.

A total number of pieces of through wiring described above is not limited to any specific number, but is generally larger than a total number of sensor pixels 12 included in the first substrate 10, and is, for example, equal to or more than three times the total number of sensor pixels 12 included in the first substrate 10.

The wiring layer 56 further includes a plurality of pad electrodes 58 provided in the insulating layer 57. Each pad electrode 58 includes metal such as Cu (copper) or Al (aluminum), for example. Each pad electrode 58 is exposed on the top surface of the wiring layer 56. Each pad electrode 58 is used as a member for electric connection between the second substrate 20 and the third substrate 30 and as a member for laminating the second substrate 20 and the third substrate 30 to each other. One of the multiple pad electrodes 58 is, for example, provided for each pixel driving line 23 and each vertical signal line 24. A total number of pad electrodes 58 (or a total number of junctions of pad electrodes 58 and pad electrodes 64 to be described later) may be smaller than the total number of sensor pixels 12 included in the first substrate 10.

An interlayer insulating film 61 is laminated onto the semiconductor substrate 31 of the third substrate 30. A surface of the third substrate 30 is laminated to a surface of the second substrate 20. The semiconductor substrate 31 includes a silicon substrate. The third substrate 30 includes a logic circuit 32 provided on an undersurface side in the semiconductor substrate 31. The third substrate 30 further includes a wiring layer 62 provided on the interlayer insulating film 61. The wiring layer 62 includes an insulating layer 63 and a plurality of pad electrodes 64 provided in the insulating layer 63. The plurality of pad electrodes 64 is electrically connected to the logic circuit 32. Each pad electrode 64 includes, for example, Cu (copper) and is exposed on the top surface of the wiring layer 62. Each pad electrode 64 is used as a member for electric connection between the second substrate 20 and the third substrate 30 and as a member for laminating the second substrate 20 and the third substrate 30 to each other. While the plurality of pad electrodes 64 is provided in the example illustrated in FIG. 19, the number of pad electrodes 64 is not limited to any specific number, and a single pad electrode 64 may be electrically connectable to the logic circuit 32. The second substrate 20 and the third substrate 30 are electrically connected to each other by joining together the pad electrodes 58 and the pad electrodes 64. That is, the gate of the transfer transistor TR (transfer gate TG) is electrically connected to the logic circuit 32 via the through wiring 54, the pad electrodes 58, and the pad electrodes 64. The third substrate 30 is laminated to the second substrate 20 such that the top surface of the semiconductor substrate 31 is directed toward the top surface side of the semiconductor substrate 21. That is, the third substrate 30 is laminated to the second substrate 20 in what is generally called a face-to-face mode.

As illustrated in FIG. 20, the first substrate 10 and the second substrate 20 are electrically connected to each other by the through wiring 54. In addition, as illustrated in FIG. 21, the second substrate 20 and the third substrate 30 are electrically connected to each other by junctions between the pad electrodes 58 and the pad electrodes 64. A width D1 of the through wiring 54 is smaller than a width D3 of the junction part between the pad electrode 58 and the pad electrode 64. A cross-sectional area of the through wiring 54 is smaller than a cross-sectional area of the junction part between the pad electrode 58 and the pad electrode 64. Hence, the through wiring 54 advantageously contributes to a reduction in area per pixel in the first substrate 10. In addition, the readout circuit 22 is formed in the second substrate 20, and the logic circuit 32 is formed in the third substrate 30. Therefore, an electric connection structure (for example, wiring, connection contacts, and the like) between the second substrate 20 and the third substrate 30 can be formed in a freer layout than an electric connection structure between the first substrate 10 and the second substrate 20. Hence, the junctions between the pad electrodes 58 and the pad electrodes 64 can be used as a structure for electrically connecting the second substrate 20 and the third substrate 30 to each other.

As described above, according to each of the foregoing embodiments, various types of transistors and wiring (through wiring 54 and the like) can be shared between pixels 12 adjacent to each other by using the mirror symmetry layout of the silicon regions 71 (semiconductor regions) and the silicon oxide film regions 72 (insulating regions). As a result, an improvement in layout efficiency in each pixel 12 can be promoted, which in turn is advantageous in miniaturizing pixels.

In a case where the photodiode 41 and various types of transistors are formed in a single substrate as in the foregoing first and second embodiments as an example, each pixel 12 may include the transfer transistor TRG, the reset transistor RST, the amplifier transistor AMP, and the selecting transistor SEL. In this case, at least any one of the reset transistor RST and the selecting transistor SEL can be shared between the pixels 12 adjacent to each other.

In a case where the photodiode 41 and the various types of transistors are formed in the single substrate as another example, each pixel 12 may include the transfer transistor TRG, the reset transistor RST, the FD transfer transistor FDG, the amplifier transistor AMP, and the selecting transistor SEL. In this case, at least any one of the reset transistor RST, the FD transfer transistor FDG, and the selecting transistor SEL can be shared between the pixels 12 adjacent to each other.

In a case of providing the first substrate 10 and the second substrate 20 that are stacked on each other and electrically connected to each other as in the foregoing third embodiment as another example, each pixel 12 of the first substrate 10 may include the transfer transistor TRG, the reset transistor RST, and the amplifier transistor AMP. In this case, the reset transistor RST can be shared between the pixels 12 adjacent to each other.

In a case where the first substrate 10 and the second substrate 20 are provided as another example, each pixel 12 of the first substrate 10 may include the transfer transistor TRG, the reset transistor RST, the FD transfer transistor FDG, and the amplifier transistor AMP. In this case, at least any one of the reset transistor RST and the FD transfer transistor FDG can be shared between the pixels 12 adjacent to each other. In addition, the translational symmetry layout of the silicon regions 71 and the silicon oxide film regions 72 between the pixels 12 adjacent to each other can avoid the anisotropy of the color mixture and thereby effectively suppress sensitivity variations between the pixels 12.

Incidentally, while the circuits illustrated in FIG. 12 and FIG. 18 include by the first substrate 10 and the second substrate 20 of the imaging element 1 having a multiple-stage pixel structure, the circuits illustrated in FIG. 12 and FIG. 18 can also similarly include a single substrate.

Thus, the imaging element 1 according to each of the foregoing embodiments is advantageous in effectively achieving both suppression of sensitivity variations between pixels 12 due to the anisotropy of the color mixture and realization of an improvement in layout efficiency.

### Examples of Application to Electronic Apparatuses

The solid-state imaging elements described above can be applied to, for example, various kinds of electronic apparatuses including imaging devices such as a digital still camera and a digital video camera, mobile telephones having an imaging function, or other apparatuses having the imaging function.

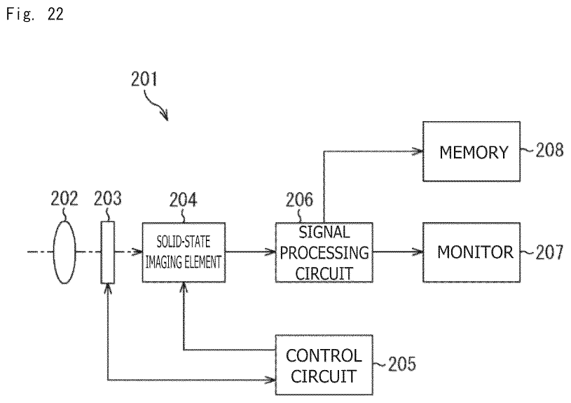

FIG. 22 is a block diagram illustrating an example of a configuration of an imaging device as an electronic apparatus to which the present technology is applied.

An imaging device 201 illustrated in FIG. 22 includes an optical system 202, a shutter device 203, a solid-state imaging element 204, a driving circuit 205, a signal processing circuit 206, a monitor 20187, and a memory 208. The imaging device 201 can capture still images and moving images.

The optical system 202 includes one or a plurality of lenses. The optical system 202 guides light (incident light) from a subject to the solid-state imaging element 204 and forms an image on a light receiving surface of the solid-state imaging element 204.

The shutter device 203 is disposed between the optical system 202 and the solid-state imaging element 204. The shutter device 203 controls a light irradiation period and a light shielding period for the solid-state imaging element 204 under control of a driving circuit 1005.

The solid-state imaging element 204 includes a package including a solid-state imaging element described above. The solid-state imaging element 204 accumulates a signal charge for a certain period of time according to the light whose image is formed on the light receiving surface via the optical system 202 and the shutter device 203. The signal charge accumulated in the solid-state imaging element 204 is transferred according to a driving signal (a timing signal) supplied from the driving circuit 205.

The driving circuit 205 drives the solid-state imaging element 204 and the shutter device 203 by outputting driving signals that control the transfer operation of the solid-state imaging element 204 and the shutter operation of the shutter device 203.

The signal processing circuit 206 performs various kinds of signal processing on the signal charge output from the solid-state imaging element 204. An image (image data) obtained by the signal processing performed by the signal processing circuit 206 is supplied to and displayed on a monitor 207, or is supplied to and stored (recorded) in the memory 208.

### Example of Application to Endoscopic Surgery System

The technology according to an embodiment of the present disclosure (present technology) can be applied to a variety of products. For example, the technology according to the present disclosure may be applied to an endoscopic surgery system.

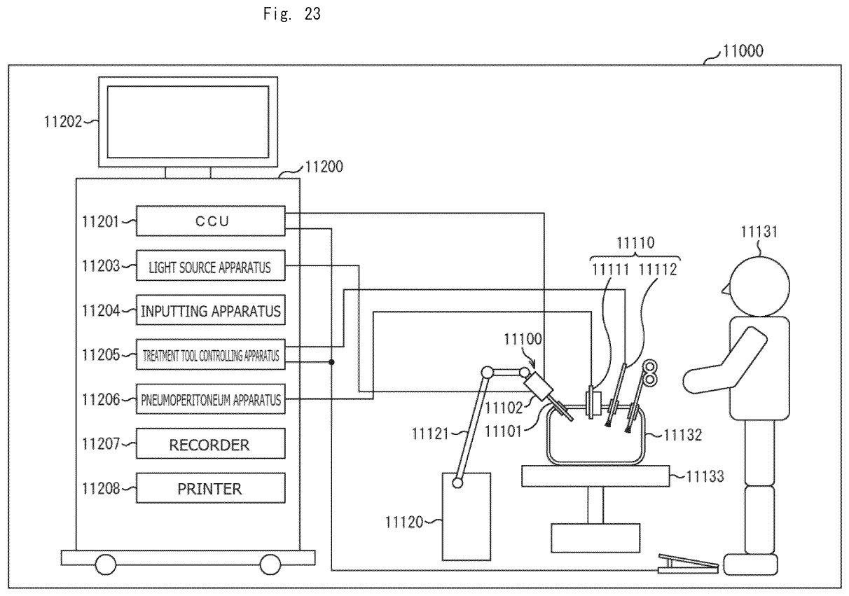

FIG. 23 is a view depicting an example of a schematic configuration of an endoscopic surgery system to which the technology according to an embodiment of the present disclosure (present technology) can be applied.

In FIG. 23, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/ or excitation light suitable for special light observation as described above.

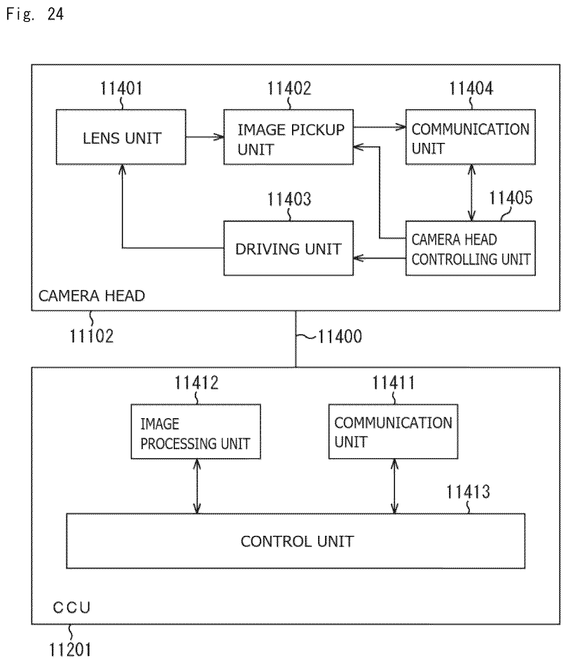

FIG. 24 is a block diagram depicting an example of a functional configuration of the camera head 11102 and the CCU 11201 depicted in FIG. 23.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image.

The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

### Example of Application to Mobile Body

The technology according to an embodiment of the present disclosure (present technology) can be applied to a variety of products. For example, the technology according to the present disclosure may be implemented as a device mounted in one of kinds of mobile bodies such as an automobile, an electric vehicle, a hybrid electric vehicle, a motorcycle, a bicycle, a personal mobility vehicle, an airplane, a drone, a vessel, and a robot.

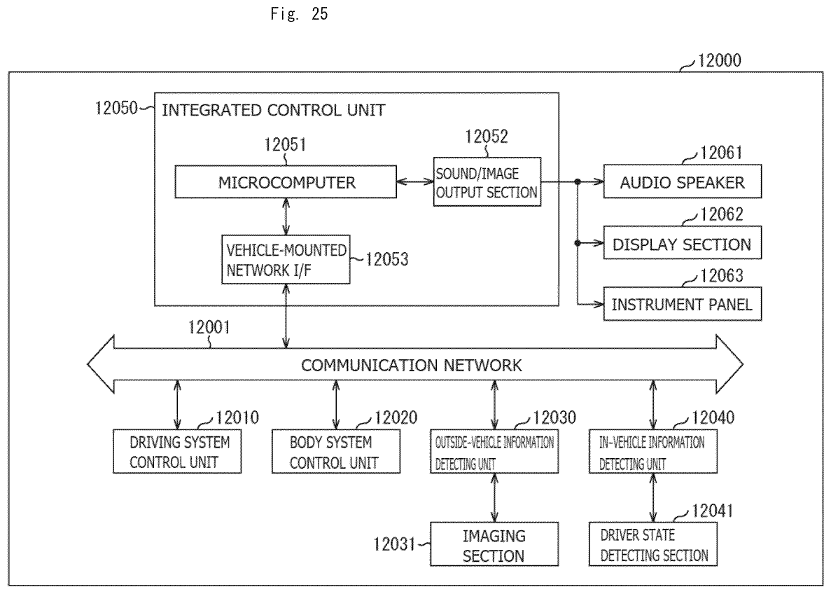

FIG. 25 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

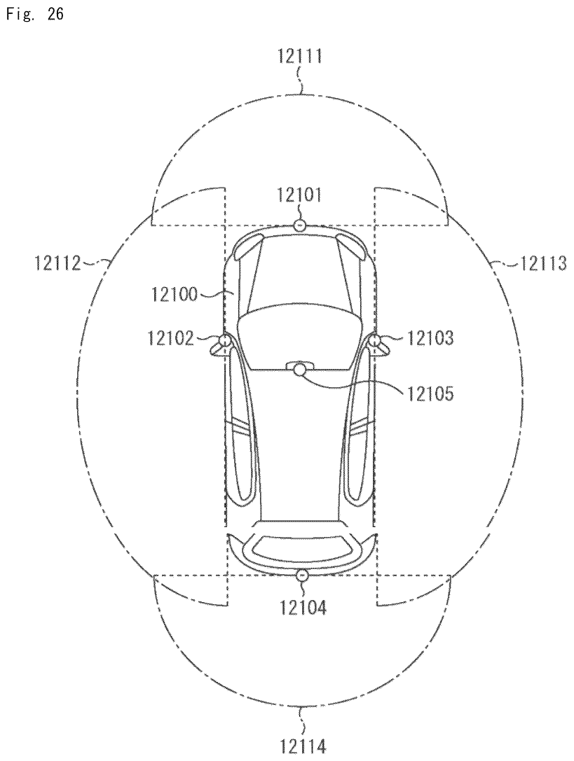

FIG. 26 is a diagram depicting an example of the installation position of the imaging section 12031.

In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 26 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object.

When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

It is to be noted that the embodiments and the modifications disclosed in the present specification are merely illustrative in all respects and are not to be construed in a limiting manner. The foregoing embodiments and modifications are susceptible of omissions, replacements, and changes in various forms. For example, the foregoing embodiments and modifications may be wholly or partially combined with each other, and an embodiment other than the foregoing may be combined with an embodiment or a modification described above. In addition, the effects of the present disclosure described in the present specification are merely illustrative, and other effects may be produced.

Technical categories in which the foregoing technical concepts are embodied are not limited to any specific kind. For example, the foregoing technical concepts may be embodied by a computer program for making a computer perform one or a plurality of procedures (steps) included in a method for manufacturing (constructing) the foregoing device (system) or a method for using the foregoing device (system). In addition, the foregoing technical concepts may be embodied by a computer readable non-transitory recording medium on which such a computer program is recorded.
(1)

A solid-state imaging element comprising:
a plurality of transistors; and
a plurality of pixels arranged two-dimensionally,
wherein at least one transistor of the plurality of transistors is shared between adjacent pixels,
wherein each pixel of the plurality of pixels includes a first and a second silicon region and a first and a second silicon oxide film region, and
wherein each silicon oxide film region surrounds a respective silicon region in a plan view.
(2)

The solid-state imaging element of (1), wherein the first silicon region is rectangular and is in a center of each pixel.
(3)

The solid-state imaging element of (1) or (2), wherein the second silicon region is a peripheral silicon region, and wherein the first silicon region is disposed inside the second silicon region.
(4)

The solid-state imaging element of any of (1) to (3), wherein the central silicon region includes a photodiode.
(5)

The solid-state imaging element of any of (1) to (4), wherein the peripheral silicon region includes two parts extending parallel in a first direction and two parts extending parallel in a second direction, and wherein the first direction is perpendicular with the second direction.
(6)

The solid-state imaging element of any of (1) to (5), wherein the peripheral silicon region has a planar shape of a rectangular frame.
(7)

The solid-state imaging element of any of (1) to (6), wherein the first silicon oxide film region is interposed between the central silicon region and the peripheral silicon region.
(8)

The solid-state imaging element of any of (1) to (7), wherein the second silicon oxide film region surrounds an outer perimeter of each pixel.
(9)

The solid-state imaging element of any of (1) to (8), wherein adjacent pixels in a first direction have mirror symmetry.
(10)

The solid-state imaging element of any of (1) to (9), wherein adjacent pixels share a reset transistor.
(11)

The solid-state imaging element of any of (1) to (10), wherein adjacent pixels share a FD transistor.
(12)

An electronic apparatus comprising:
a plurality of transistors;
a plurality of pixels arranged two-dimensionally;
a processing circuit that processes a generated image signal,
wherein at least one transistor of the plurality of transistors is shared between adjacent pixels,
wherein each pixel of the plurality of pixels includes a first and a second silicon region and a first and a second silicon oxide film region, and wherein each silicon oxide film region surrounds a respective silicon region.
(13)

The electronic apparatus of (12), wherein the first silicon region is rectangular and is in a center of each pixel, and wherein the central silicon region includes a photodiode.
(14)

The electronic apparatus of any of (12) or (13), wherein the second silicon region is a peripheral silicon region, and wherein the first silicon region is disposed inside the second silicon region.
(15)

The electronic apparatus of any of (12) to (14), wherein the peripheral silicon region has a planar shape of a rectangular frame.
(16)

The electronic apparatus of any of (12) to (14), wherein the first silicon oxide film region is interposed between the central silicon region and the peripheral silicon region.
(17)

The electronic apparatus of any of (12) to (16), wherein the second silicon oxide film region surrounds an outer perimeter of each pixel.
(18)

The electronic apparatus of any of (12) to (17), wherein adjacent pixels in a first direction have mirror symmetry.
(19)

The electronic apparatus of any of (12) to (18), wherein adjacent pixels share a reset transistor.
(20)

The electronic apparatus of any of (12) to (19), wherein adjacent pixels share a FD transistor.

### <Notes>

### REFERENCE SIGNS LIST

1: Imaging element
10: First substrate
11: Semiconductor substrate
12: Pixel
13: Pixel region
20: Second substrate
21: Semiconductor substrate
22: Circuit
23: Pixel driving line
24: Vertical signal line
30: Third substrate
31: Semiconductor substrate
32: Logic circuit
33: Vertical driving circuit
34: Column signal processing circuit
35: Horizontal driving circuit
36: System control circuit
40: Color filter
41: Photodiode
42: p-well layer
43: Pixel separating portion
43a: STI pixel separating portion
43b: FTI pixel separating portion
44: p-well layer
45: Fixed charge film
46: Insulating layer
50: Light receiving lens
51: Interlayer insulating film
52: Insulating layer
53: Insulating layer
54: Through wiring
55: Connection wiring
56: Wiring layer
57: Insulating layer
58: Pad electrode
59: Connecting portion
61: Interlayer insulating film
62: Wiring layer
63: Insulating layer
64: Pad electrode
71: Silicon region
72: Silicon oxide film region
75: Wiring
77: Wiring layer
78: Connection layer
78a: Semiconductor layer
79: Wiring layer
AMP: Amplifier transistor
FDG: FD transfer transistor
FTI: Full trench isolation
KOZ: Wiring-to-semiconductor interval
L: Incident light
Lr: Reflected light
RST: Reset transistor
SEL: Selecting transistor
STI: Shallow trench isolation
SW: Switch
TRG: Transfer transistor

What is claimed is:

1. A solid-state imaging element, comprising:
a plurality of transistors; and
a plurality of pixels arranged two-dimensionally,
wherein at least one transistor of the plurality of transistors is shared between adjacent pixels,
wherein each pixel of the plurality of pixels includes a first and a second silicon region and a first and a second silicon oxide film region, and
wherein each silicon oxide film region surrounds a respective silicon region in a plan view.

2. The solid-state imaging element according to claim 1, wherein the first silicon region is rectangular and is in a center of each pixel.

3. The solid-state imaging element according to claim 2, wherein the second silicon region is a peripheral silicon region, and wherein the first silicon region is disposed inside the second silicon region.

4. The solid-state imaging element according to claim 2, wherein the central silicon region includes a photodiode.

5. The solid-state imaging element according to claim 3, wherein the peripheral silicon region includes two parts extending parallel in a first direction and two parts extending parallel in a second direction, and wherein the first direction is perpendicular with the second direction.

6. The solid-state imaging element according to claim 3, wherein the peripheral silicon region has a planar shape of a rectangular frame.

7. The solid-state imaging element according to claim 3, wherein the first silicon oxide film region is interposed between the central silicon region and the peripheral silicon region.

8. The solid-state imaging element according to claim 7, wherein the second silicon oxide film region surrounds an outer perimeter of each pixel.

9. The solid-state imaging element according to claim 1, wherein adjacent pixels in a first direction have mirror symmetry.

10. The solid-state imaging element according to claim 1, wherein adjacent pixels share a reset transistor.

11. The solid-state imaging element according to claim 1, wherein adjacent pixels share a FD transistor.

12. An electronic apparatus, comprising:
a plurality of transistors;
a plurality of pixels arranged two-dimensionally;
a processing circuit that processes a generated image signal,
wherein at least one transistor of the plurality of transistors is shared between adjacent pixels,
wherein each pixel of the plurality of pixels includes a first and a second silicon region and a first and a second silicon oxide film region, and
wherein each silicon oxide film region surrounds a respective silicon region.

13. The electronic apparatus according to claim 12, wherein the first silicon region is
rectangular and is in a center of each pixel, and wherein the central silicon region includes a photodiode.

14. The electronic apparatus according to claim 13, wherein the second silicon region is a peripheral silicon region, and wherein the first silicon region is disposed inside the second silicon region.

15. The electronic apparatus according to claim 14, wherein the peripheral silicon region has a planar shape of a rectangular frame.

16. The electronic apparatus according to claim 14, wherein the first silicon oxide film region is interposed between the central silicon region and the peripheral silicon region.

17. The electronic apparatus according to claim 12, wherein the second silicon oxide film region surrounds an outer perimeter of each pixel.

18. The electronic apparatus according to claim 12, wherein adjacent pixels in a first direction have mirror symmetry.

19. The electronic apparatus according to claim 12, wherein adjacent pixels share a reset transistor.

20. The electronic apparatus according to claim 12, wherein adjacent pixels share a FD transistor.
